(19) United States
(12) Patent Application Publication
(10) Pub. No.: US 2007/0176292 A1
(43) Pub. Date: Aug. 2, 2007

(54) Bonding pad structure

(75) Inventors: Hsien-Wei Chen, Tainan (TW); Hsueh-Chung Chen, Taipei (TW)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(73) Assignee: TAIWAN SEMICONDUCTOR MANUFACTURING CO., LTD.

(21) Appl. No.: 11/340,721

(22) Filed: Jan. 27, 2006

(51) Int. Cl. H01L 23/48

(52) U.S. Cl. 257/750

(57) ABSTRACT

Bonding pad structure is provided. The bonding pad structure comprises a semiconductor substrate having a top metal layer thereon, a first passivation layer formed on the semiconductor substrate and the top metal layer, and a bonding pad formed on the first passivation layer and connected to the top metal layer. The bonding pad structure further comprises a second passivation layer formed on the bonding pad and the first passivation layer and a solder bump or bond wire formed on the bonding pad and an upper surface of the second passivation layer, wherein at least one of the first passivation layer and the second passivation layer comprises a photosensitive polymer material.

### BACKGROUND

The present invention relates to semiconductor fabrication, in particular, to bonding pad structures and methods of forming the same.

The reduction of the feature sizes of semiconductor devices using advanced semiconductor techniques, such as high-resolution lithography and directional etching, have dramatically increased the device packing density on integrated circuit chips formed on a substrate. However, as device packing density increases, the number of electrical metal interconnect layers on the chip must be increased to effectively wire up the discrete devices on the substrate while reducing the chip size. Typically after completing the multilevel interconnect structure, aluminum bonding pads are formed on the top surface of the interconnect structure to provide external electrical connections to the chip. A passivation layer is then applied to passivate the chip from moisture and contamination.

An organic polymer stress buffer layer is typically formed on a second oxide or nitride passivation layer which is formed on the first oxide or nitride passivation layer to release stress caused by packaging.

U.S. Pat. No. 6,387,795 to Shao discloses a wafer-level packaging process. The wafer has a plurality of bonding pads thereon exposed through a passivation layer. A stress buffer layer is formed, through which a plurality of first openings of the stress buffer layer are formed. Some problems, however, regarding process complexity and manufacturing cost arise.

Therefore, bonding pad structures and methods of forming the same capable of reducing process complexity and manufacturing cost are desirable.

### SUMMARY

It is therefore an object of the invention to provide bonding pad structures and methods of forming the same to reduce process complexity and manufacturing cost.

An embodiment of a bonding pad structure comprises a semiconductor substrate having a top metal layer thereon, a first passivation layer formed on the semiconductor substrate and the top metal layer, and a bonding pad formed on the first passivation layer and connected to the top metal layer. The bonding pad structure further comprises a second passivation layer formed on the bonding pad and the first passivation layer and a solder bump or a bond wire formed on the bonding pad and an upper surface of the second passivation layer, wherein at least one of the first passivation layer and the second passivation layer comprises a photosensitive polymer material.

An embodiment of a method of forming a bonding pad structure comprises providing a semiconductor substrate having a top metal layer thereon. A first passivation layer is formed on the semiconductor substrate and the top metal layer. A bonding pad is formed on the first passivation layer and connected to the top metal layer. A second passivation layer is formed on the bonding pad and the first passivation layer, wherein at least one of the first passivation layer and the second passivation layer comprises a photosensitive polymer material.

### DESCRIPTION OF THE DRAWINGS

FIGS. 1A to 1F are cross sections showing an exemplary process of forming a bonding pad structure for a solder bump of the present invention.

FIGS.2A to 2F are cross sections showing another exemplary process of forming a bonding pad structure for a solder bump of the present invention.

FIG.3 is a cross section showing a bonding pad structure for a solder bump of an embodiment of the present invention.

FIG. 4 is a cross section showing a bonding pad structure for a solder bump of another embodiment of the present invention.

FIG. 5 is a cross section showing a bonding pad structure for a wire bonding of an embodiment of the present invention.

### DETAILED DESCRIPTION

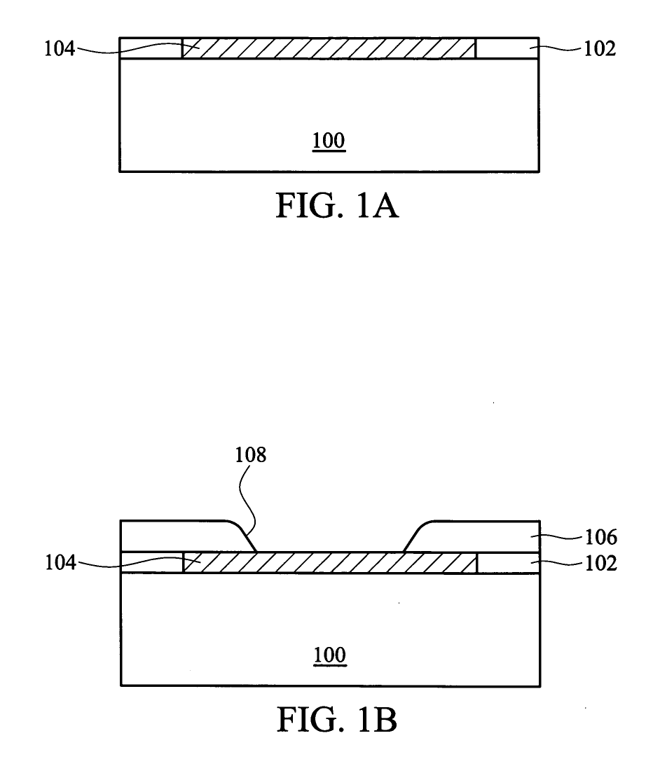

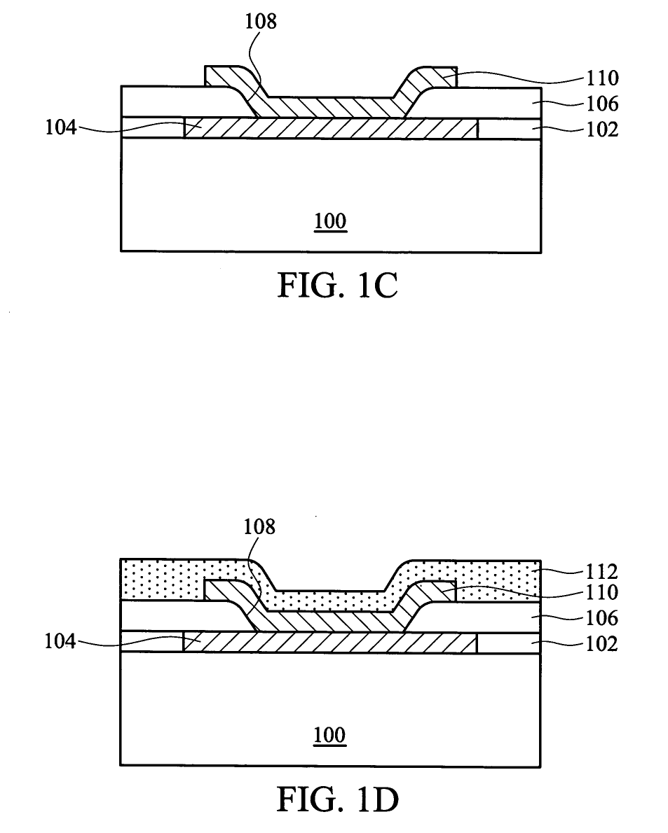

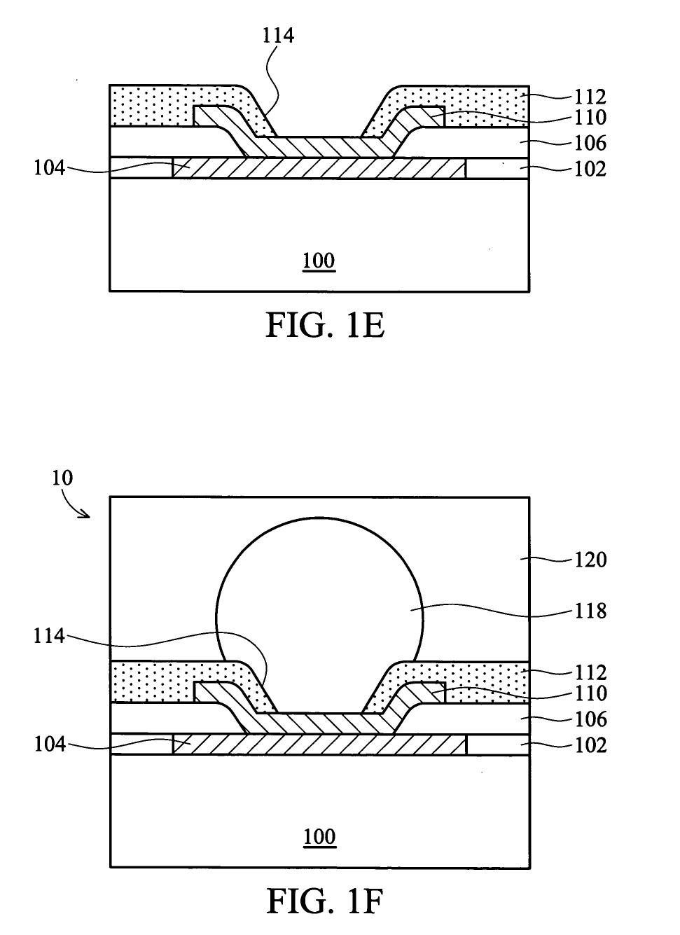

As shown in FIG.1A, a semiconductor substrate 100 having a top metal layer 104 thereon is provided. The top metal layer 104 may be an uppermost pad of the multiple interconnects linking the semiconductor elements together. An inter-metal dielectric layer 102 is formed on the semiconductor substrate 100 and coplanar with the top metal layer 104. The inter-metal dielectric layer 102 comprises a low-k material with a dielectric constant of less than 3.2, for example a polymer based dielectric or an inorganic material such as a carbon-doped oxide. The top metal layer 104 may comprise aluminum, copper, or an alloy thereof.

Referring to FIG. 1B, the first passivation layer 106 is formed on the semiconductor substrate 100, the top metal layer 104 and the inter-metal dielectric layer 102 by chemical vapor deposition such as plasma enhanced chemical vapor deposition (PECVD), low. pressure chemical vapor deposition (LPCVD), or high density plasma density plasma chemical vapor deposition (HDPCVD) while using a silicon-containing material, an oxygen-containing material, or nitride-containing material. Specially, silicon oxide, silicon nitride or silicon oxynitride can be used as the first passivation layer 106. The first passivation layer 106 has an opening 108 formed by selectively etching the first passivation layer 106 so that the top metal layer 104 is exposed through the opening 108. That is, a photoresist pattern (not shown) is formed on the first passivation layer 106 by photolithography consisting of photoresist spin coating, soft baking, exposing, developing, and hard baking. The first passivation layer 106 is anisotropically etched by reactive ion etching (RIE) or isotropically etched by a wet echant until the top metal layer 104 is exposed and the opening 108 is created. The photoresist pattern is stripped from the surface of the first passivation layer 106 using wet stripping or an oxidizing ambient such as oxygen plasma ashing.

As shown in FIG. 1C, a bonding pad 110 is formed on the first passivation layer 106 and connected to the top metal layer 104 through the opening 108. The bonding pad 110, consisting of aluminum, copper or an alloy thereof, extends to the upper surface of the first passivation layer 106. The bonding pad 110 can be deposited by physical vapor deposition (PVD) such as a sputtering deposition using a sputtering target made of aluminum, copper or an alloy thereof followed by defining the deposited layer for the bonding pad 110 with photolithography and etching.

As shown in FIG. 1D, the second passivation layer 112 is formed on the bonding pad 110 and the first passivation layer 106 by coating while using an organic photosensitive polymer such as polyimide, polyurethane or a copolymer thereof. The second passivation layer 112 may be composed of the organic polymer with imide, epoxy or urea functional group, which might be also have soft domains such as nano-scaled pores or a soft plastic such as a linear hydroxyl group (linear ethylene oxide) therein. For example, nano-scaled pores having dimensions of about 50 nm to 5000 nm, are distributed within the polyimide based layer. Alternately, the second passivation layer 112 may comprise polymethylmethacrylate (PMMA), either photosensitive or not photosensitive.

The second passivation layer 112 serves as a stress buffer absorbing or releasing thermal or mechanical stress caused by packaging of the chip. The soft domains help the second passivation layer 112 to absorb or release stress. Thus, cracks at the edge of the wafer or the chip and the inter-metal dielectric layer 102 can be avoided.

Referring to FIG. 1E, the second passivation layer 112 is pre-baked followed by exposure to radiation through a photomask (not shown). The second passivation layer 112 is then developed to form an opening 114 therein, thus the bonding pad 110 is exposed. The second passivation layer 112 is then cured and strengthened at a temperature ranging from 350° C. to 400° C.

As shown in FIG. 1F, a solder bump 118 is formed on the bonding pad 110 and contacts with an upper surface of the second passivation layer 112. An under bump metal (UBM) (not shown) is preferably formed on the bonding pad 110 before forming the solder bump 118. Next, an underfill compound 120, such as an epoxy resin, is formed on the solder bump 118 and directly contacts with the second passivation layer 112. The underfill compound 120 is typically formed between the second passivation layer 112 and a printed circuit board (not shown).

FIG. 1F shows a bonding pad structure 10 comprising a semiconductor substrate 100 having a top metal layer 104 thereon and a first passivation layer 106 formed on the semiconductor substrate 100. The bonding pad structure 10 further comprises a bonding pad 110 formed on the first passivation layer 106, and a second passivation layer 112 made of a photosensitive polymer material formed on the bonding pad 110 and the first passivation layer 106. The bonding pad structure 10 further comprises a solder bump 118 formed on the bonding pad 110 and an upper surface of the second passivation layer 112, and an underfill compound 120 directly contacted with the second passivation 112.

As compared to a conventional method, there is no need to form a polyimide buffer on the second passivation layer made of an inorganic material such as silicon oxide or silicon nitride, thus, the exemplary process can be simplified. Moreover, when the second passivation layer 112 is photosensitive, there is no need to form and remove a photoresist pattern on the second passivation layer 112 serving as an etching mask while forming the opening 114. Therefore, process complexity and manufacturing cost may be reduced.

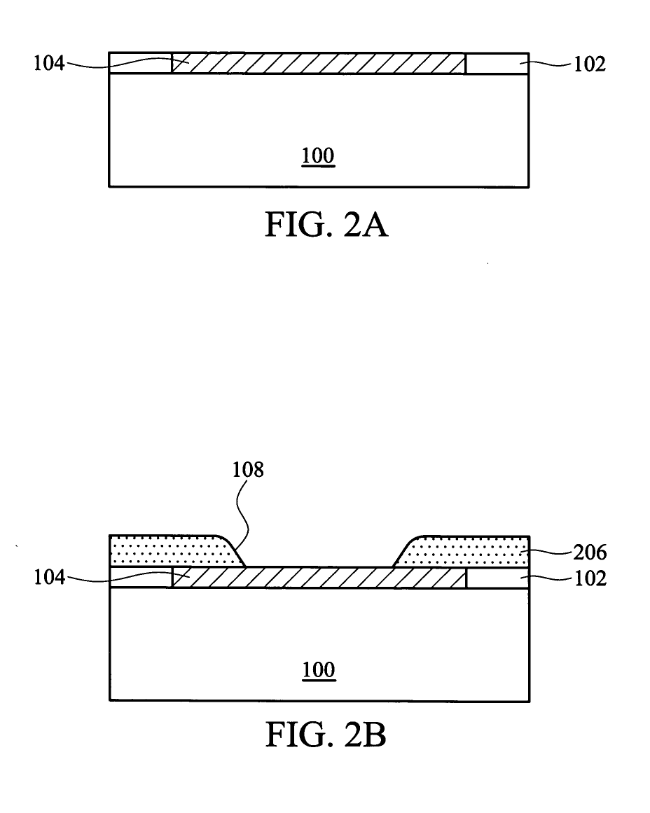

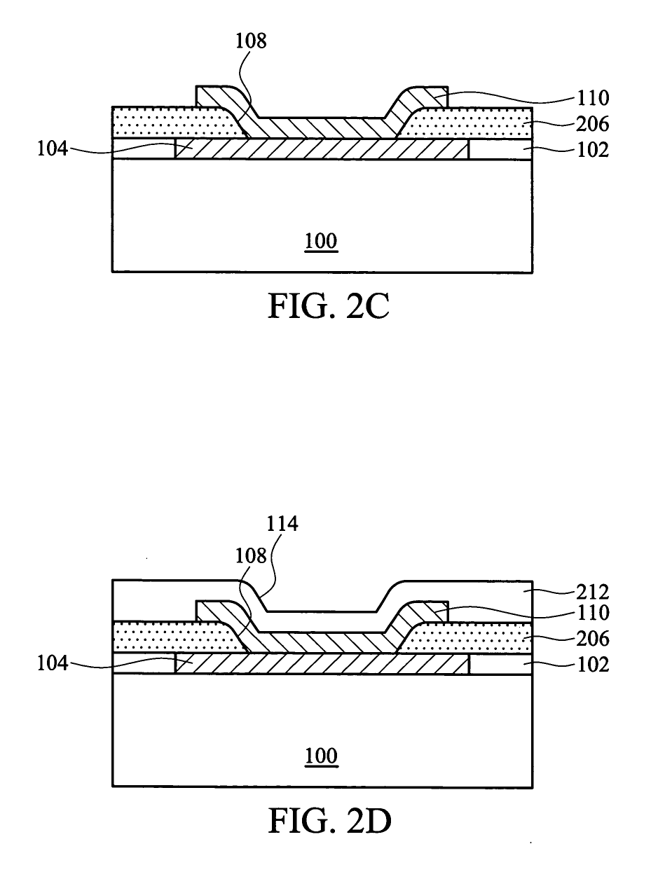

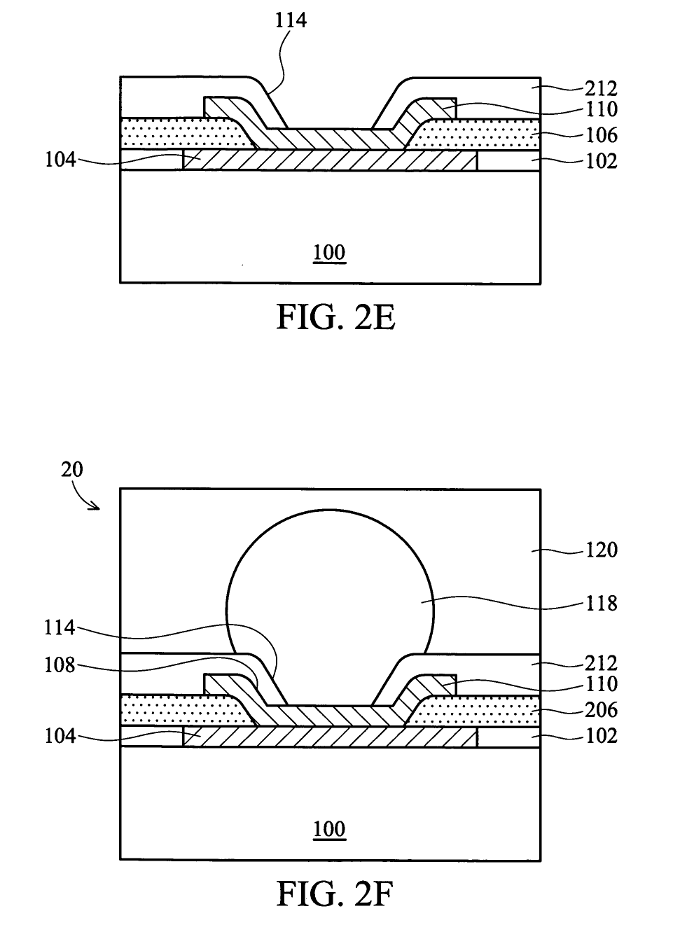

The exemplary process as shown in FIGS.2A to 2F is substantially similar to that as shown in FIGS. 1A to 1F except that the first passivation layer 206 comprises an organic photosensitive polymer with imide, urea, or epoxy functional groups and the second passivation layer 212 comprises the same material as the first passivation layer 106 as described. That is, the second passivation layer 212 may comprise a silicon-containing material, an oxygen-containing material, or nitride-containing material.

The first passivation layer 206 may comprise a copolymer with at least two functional groups of imide, urea, or epoxy, and is made by physical blending (polymer blend) or chemical reaction (polymer synthesis). The first passivation layer 206 may be composed of an organic polymer with imide, urea or epoxy functional groups, which might be also have soft domains such as nano-scaled pores or a soft plastic such as a linear hydroxyl group (linear ethylene oxide) therein. For example, nano-scaled pores have dimensions of about 50 nm to 5000 nm. Alternately, the first passivation layer 206 may comprise polymethylmethacrylate (PMMA), either photosensitive or not photosensitive. The first passivation layer 206 serves as a stress buffer absorbing or releasing thermal or mechanical stress caused by packaging of the chip.

FIG. 2F shows a bonding pad structure 20 comprising a semiconductor substrate 100 having a top metal layer 104 thereon and a first passivation layer 206 formed on the semiconductor substrate 100 and the top metal layer 104. The first passivation layer 206 is made of a photosensitive polymer material. The bonding pad structure 20 further comprises a bonding pad 110 formed on the first passivation layer 206 and connected to the top metal layer 104, and a second passivation layer 212 formed on the bonding pad 110 and the first passivation layer 206. Also, the bonding pad structure 20 further comprises a solder bump 118 formed on the bonding pad 110 and an upper surface of the second passivation layer 212. An underfill compound 120, such as an epoxy resin, is formed on the solder bump 118 and directly contacted with the second passivation layer 212.

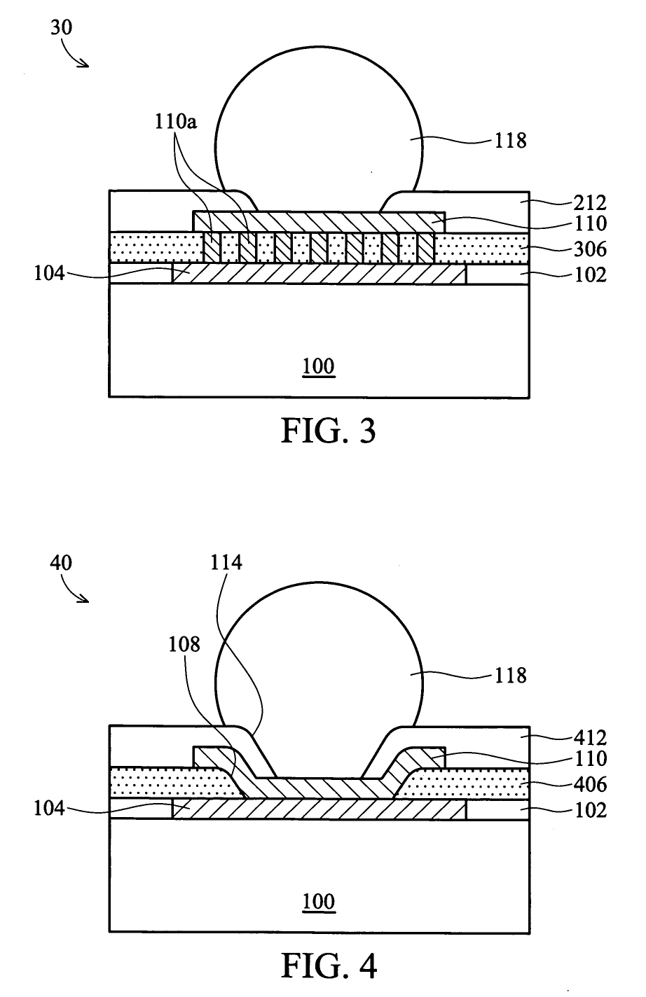

FIG.3 is a cross section showing a bonding pad structure 30 for a solder bump of an embodiment of the present invention. The bonding pad structure 30 is substantially similar to the bonding pad structure 20 as shown in FIG. 2F except that a plurality of metal plugs 110a are interposed between the top metal layer 104 and the bonding pad 110. The metal plugs 110a are vertically separated from each other by the first passivation layer 306 and preferably comprise aluminum, copper or an alloy thereof. In order to increase the buffer efficiency of first passivation layer 306, the metal plugs 110a are disposed within the first passivation layer 306. That is to say, the metal plugs 110a help the first passivation layer 306 to absorb or release stress in the bumping process.

FIG. 4 is a cross section showing a bonding pad structure for a solder bump of another embodiment of the present invention.

The bonding pad structure 40 is substantially similar to the bonding pad structure 10 or the bonding pad structure 20 as shown in FIG.1F or FIG. 2F except that both the first passivation layer 406 and the second passivation layer 412 are made of a photosensitive polymer material. The opening 108 within the first passivation layers 406 can be created by exposure, developing and curing without formation and removal of a photoresist pattern for the opening 108, etching and stripping the photoresist pattern. Also, the opening 114 within the second passivation layer 412 can be created by exposure, developing and curing without formation and removal of a photoresist pattern for the opening 114 etching and stripping a photoresist pattern for the opening 114. Therefore, the process of forming the bonding pad structure 40 can be further simplified.

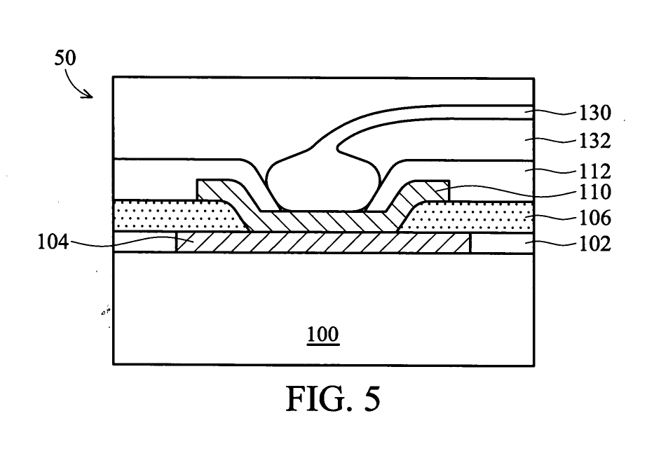

FIG. 5 is a cross section showing a bonding pad structure for wire bonding. The bonding pad structure 50 comprises a semiconductor substrate 100 having a top metal layer 104 within the inter-metal dielectric layer 102. A first passivation layer 106 is formed on the semiconductor substrate 100 and the top metal layer 104. The bonding pad structure 50 further comprises a bonding pad 110 formed on the first passivation layer 106 and connected to the top metal layer 104. The bonding pad structure 50 further comprises a second passivation layer 112 formed on the bonding pad 110 and the first passivation layer 106, and a bond wire 130 formed on the bonding pad 110. At least one of the first passivation layer 106 and the second passivation layer 112 comprises a photosensitive polymer material. The molding compound 132 covers the bond wire 130 and directly contacted with the second passivation layer 112.

As compared with a conventional method, there is no need to form and remove a photoresist pattern on the first and/or second passivation layers as an etching mask while forming the openings. Thus, process complexity and manufacturing cost may be reduced.

While the invention has been described with reference to various illustrative embodiments, the description is not intended to be construed in a limiting sense. Various modifications of the illustrative embodiments, as well as other embodiments of the invention, will be apparent to those people skilled in the art upon reference to this description. It is therefore contemplated that the appended claims will cover any such modifications or embodiments as may fall within the scope of the invention defined by the following claims and their equivalents.

What is claimed is:

1. A bonding pad structure, comprising:
a semiconductor substrate having a top metal layer thereon;
a first passivation layer formed on the semiconductor substrate and comprising an opening exposing a portion of the top metal layer;
a bonding pad formed on the first passivation layer and connected to exposed portion of the top metal layer; and
a second passivation layer formed on the bonding pad and the first passivation layer, and comprising an opening exposing a portion of the bonding pad; and
a solder bump formed on the exposed portion of the bonding pad and the second passivation layer;
wherein at least one of the first passivation layer and the second passivation layer comprises a photosensitive polymer material.

2. The bonding pad structure as claimed in claim 1, wherein the first passivation layer comprises silicon-containing material, oxygen-containing material, or nitride-containing material, and the second passivation layer comprises an organic polymer.

3. The bonding pad structure as claimed in claim 1, wherein the second passivation layer comprises silicon-containing material, oxygen-containing material, or nitride-containing material, the first passivation layer comprises an organic polymer.

4. The bonding pad structure as claimed in claim 1, wherein the first and second passivation layers comprise an organic polymer.

5. The bonding pad structure as claimed in claim 1, further comprising a plurality of metal plugs interposed between the top metal layer and the bonding pad.

6. The bonding pad structure as claimed in claim 1, wherein the photosensitive polymer material contains pores therein.

7. The bonding pad structure as claimed in claim 1, further comprising an inter-metal dielectric layer coplanar with the top metal layer.

8. The bonding pad structure as claimed in claim 1, further comprising an underfill compound covered on the solder bump and directly contacted with the second passivation layer.

9. A bonding pad structure, comprising:
a semiconductor substrate having a top metal layer thereon;
a first passivation layer formed on the semiconductor substrate and comprises an opening exposing a portion of the top metal layer;
a bonding pad formed on the first passivation layer and connected to the exposed portion of the top metal layer; and
a second passivation layer formed on the bonding pad and the first passivation layer, and comprising an opening exposing a portion of the bonding pad; and
a bond wire formed on the exposed portion of the bonding pad;
wherein at least one of the first passivation layer and the second passivation layer comprises a photosensitive polymer material.

10. The bonding pad structure as claimed in claim 9, wherein the first passivation layer comprises silicon-containing material, oxygen-containing material, or nitride-containing material, the second passivation layer comprises an organic polymer.

11. The bonding pad structure as claimed in claim 9, wherein the second passivation layer comprises silicon-containing material, oxygen-containing material, or nitride-containing material, the first passivation layer comprises an organic polymer.

12. The bonding pad structure as claimed in claim 9, wherein the first and second passivation layers comprise an organic polymer.

13. The bonding pad structure as claimed in claim 9, further comprising a plurality of metal plugs interposed between the top metal layer and the bonding pad.

14. The bonding pad structure as claimed in claim 9, wherein the photosensitive polymer material contains pores therein.

15. The bonding pad structure as claimed in claim 9, further comprising an inter-metal dielectric layer coplanar with the top metal layer.

16. The bonding pad structure as claimed in claim 9, further comprising a molding compound covered on the bond wire and directly contacted with the second passivation layer.
